(19) United States
(12) Patent Application Publication
(10) Pub. No.: US 2006/0156159 A1
(43) Pub. Date: Jul. 13, 2006

(54) Audio data interpolation apparatus

(76) Inventor: Seiji Harada, Tokyo (JP)

Correspondence Address: DRINKER BIDDLE & REATH (DC), 1500 K STREET, N.W., SUITE 1100, WASHINGTON, DC, 20005-1209, US

(21) Appl. No.: 11/274,471

(22) Filed: Nov. 16, 2005

(30) Foreign Application Priority Data
Nov. 18, 2004 (JP) 2004-333948

(51) Int. Cl. H04L 1/00; H03M 13/00; G08C 25/00; G06F 11/00; G06F 11/30

(52) U.S. Cl. 714/746

(57) ABSTRACT

An audio data interpolation apparatus and method for creating interpolated data corresponding to an error position in audio data using a filter having a filter characteristic that corresponds to a feature amount of the audio data, in accordance with at least data pieces before the error position of the audio data, and replacing the data portion at the error position of the audio data with the interpolated data.

### BACKGROUND OF THE INVENTION

1. Field of the Invention

The present invention relates to an interpolation apparatus for interpolating an error portion of audio data such as PCM data.

2. Description of the Related Background Art

Recently, in order to enjoy music, audio data representing a music piece is downloaded onto a computer via the Internet, and the music piece is reproduced in accordance with the audio data. Errors such as failures of data may occur in the downloaded audio data depending on the data transmission condition of the Internet. To interpolate these error portions, an audio data interpolation apparatus is employed (see Japanese Patent Publication 3041928, Japanese Unexamined Patent Application Publication 2000-214875, Japanese Unexamined Patent Application Publication 2002-41088, Japanese Unexamined Patent Application Publication H9-161417, and Japanese Unexamined Patent Application Publication 2003-99096, for example).

As shown in FIG. 1, for example, a conventional audio data interpolation apparatus is constituted by an error position detecting unit 11, a PCM generating unit 12, a buffer 13, an interpolation processing unit 14, a delay unit 15, and an output switching unit 16. In the interpolation apparatus, input data is compressed audio data in a compression format such as MP3, but uncompressed audio data may also be used.

The error position detecting unit 11 detects a frame including an error in the input data. When MP3 format audio data, for example, is used as the input data, an error check item for a two-byte CRC (cyclic redundancy check) is provided immediately after the frame header of each frame, and when the value of the error check does not match a CRC value calculated on the basis of the main data in a frame, it is determined that the frame is an error frame. When the error position detecting unit 11 detects a frame including an error in the input data, an error detection signal is generated and transmitted to the PCM generating unit 12.

The PCM generating unit 12 is a decoder which decodes the input data, generates PCM data, and outputs the generated PCM data to the buffer 13. When a frame including an error is output in accordance with the error detection signal from the error position detecting unit 11, the PCM generating unit 12 also outputs a switching signal indicating the frame (the frame number) to the output switching unit 16. The buffer 13 holds the PCM data supplied by the PCM generating unit 12 in block units corresponding to the frames of the input data, and outputs the held PCM data to the delay unit 15 at a predetermined timing.

The interpolation processing unit 14 receives the PCM data of the blocks in front and rear of the error block from the buffer 13 using a recursive filter, creates interpolated PCM data corresponding to the error block, and outputs the interpolated PCM data to the data switching unit 16.

The delay unit 15 delays the PCM data from the buffer 13 by the amount of time required for the interpolation processing unit 14 to create the interpolated PCM data, and then outputs the delayed PCM data to the output switching unit 16.

The output switching unit 16 typically receives and outputs the PCM data supplied by the delay unit 15, and receives and outputs the interpolated PCM data supplied by the interpolation processing unit 14 in response to the frame indicated by the switching signal.

With the above configuration, when the error position detecting unit 11 detects a frame including an error in the input data, an error detection signal is generated. The error detection signal is then output to the output switching unit 16 from the PCM generating unit 12 as a switching signal indicating the frame which includes the error. The PCM data that is generated by the PCM generating unit 12 passes through the delay unit 15, and is typically output by the output switching unit 16. At the time of the block which corresponds to the frame indicated by the switching signal, the output switching unit 16 outputs the interpolated PCM data supplied by the interpolation processing unit 14.

In the conventional audio data interpolation apparatus, when the PCM data generated by the PCM generating unit 12 switches to the interpolated PCM data created by the interpolation processing unit 14, the listener may feel unnatural by the reproduced sound of the interpolated portion, depending on the content.

### SUMMARY OF THE INVENTION

An object of the present invention is to provide an audio data interpolation apparatus which is capable of reducing the unnatural feeling caused by the reproduced sound of an interpolated portion.

An audio data interpolation apparatus according to the present invention is an apparatus for interpolating an error portion of audio data, comprising: an error position detecting unit which detects an error position in said audio data; an audio feature amount detecting unit which detects a feature amount of said audio data; an interpolated data creating unit which creates interpolated data corresponding to said error position of said audio data using a filter having a filter characteristic that corresponds to said feature amount of said audio data, in accordance with at least data pieces before said error position of said audio data; and a switching unit which replaces the data portion at said error position of said audio data with said interpolated data.

An audio data interpolation method according to the present invention is a method for interpolating an error portion of audio data, and comprises the steps of: detecting an error position in the audio data; detecting a feature amount of the audio data; creating interpolated data corresponding to the error position of the audio data using a filter having a filter characteristic that corresponds to the feature amount of the audio data, in accordance with at least data pieces before the error position of the audio data; and replacing the data portion at the error position of the audio data with the interpolated data.

### BRIEF DESCRIPTION OF THE DRAWINGS

FIG. 1 is a block diagram showing a conventional audio data interpolation apparatus;

FIG. 2 is a block diagram showing an embodiment of the present invention;

FIG. 3 is a circuit diagram showing the constitution of an interpolation processing unit in the apparatus shown in FIG. 2;

FIG. 4 is a flowchart showing operations of an audio feature amount detecting unit and an interpolation parameter generating unit in the apparatus shown in FIG. 2;

FIG. 5 is a view showing a maximum value and a minimum value of m blocks; and

FIG. 6 is a view showing variation in the amplitude of audio signals in various programs.

### DETAILED DESCRIPTION OF THE INVENTION

An embodiment of the present invention will be described in detail below with reference to the drawings.

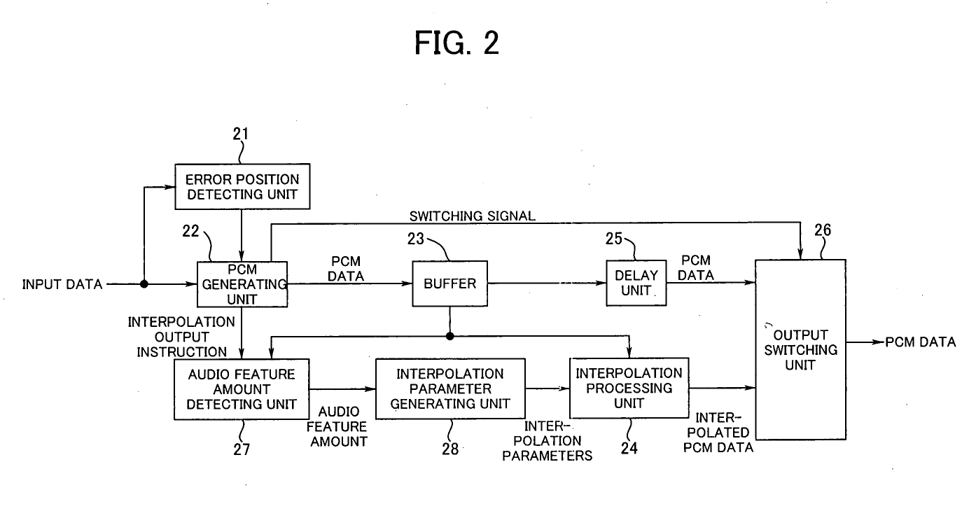

FIG. 2 is a block diagram showing the configuration of an audio data interpolation apparatus according to the present invention.

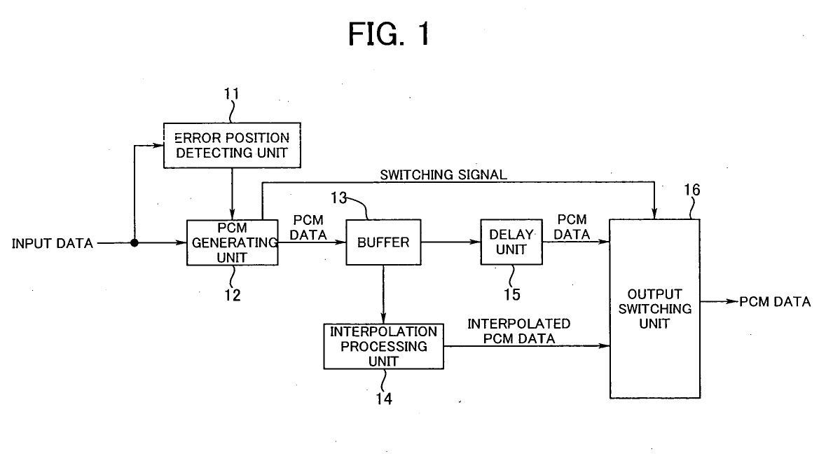

As shown in FIG. 2, the audio data interpolation apparatus comprises an error position detecting unit 21, a PCM generating unit 22, a buffer 23, an interpolation processing unit 24, a delay unit 25, an output switching unit 26, an audio feature amount detecting unit 27, and an interpolation parameter generating unit 28. The error position detecting unit 21, PCM generating unit 22, buffer 23, and output switching unit 26 are equal to the error position detecting unit 11, PCM generating unit 12, buffer 13, and output switching unit 16, respectively, of the conventional audio data interpolation apparatus shown in FIG. 1. When the PCM generating unit 22 is supplied with an error detection signal from the error position detecting unit 21, the PCM generating unit 22 sends an interpolation output instruction to the audio feature amount detecting unit 27. The buffer 23 is capable of holding PCM data in an amount corresponding to m blocks, which will be described below.

In response to an interpolation output instruction from the PCM generating unit 22, the audio feature amount detecting unit 27 detects an audio feature amount in accordance with the PCM data held in the buffer 23. The audio feature amount is the maximum value and minimum value of the amplitude level of the audio signal. The maximum value and minimum value are absolute values, but may be the maximum value and minimum value of the plus level alone.

The interpolation parameter generating unit 28 generates interpolation parameters in accordance with the maximum value and minimum value, or in other words the audio feature amount, detected by the audio feature amount detecting unit 27. The interpolation parameters are multiplication coefficients k1, k2, . . . , kj, g1, g2, . . . , gj of the interpolation processing unit 24. Each of the multiplication coefficients k1, k2, . . . , kj takes a value of no less than 0 and less than or equal to 1, and each of the multiplication coefficients g1, g2, . . . , gj takes a value of no less than 0 and less than or equal to 1.

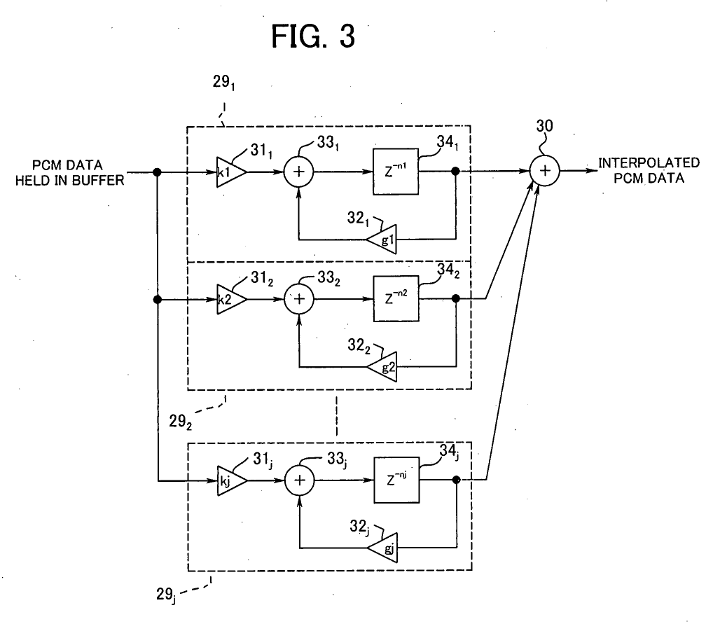

As shown in FIG. 3, the interpolation processing unit 24 includes j IIR filters 29₁ to 29ⱼ, which are recursive filters, and an adder 30 provided at the output of the IIR filters 29₁ to 29ⱼ. The IIR filter 29₁ is constituted by two coefficient multipliers 31₁, 32₁, an adder 33₁ and a delay element 34₁. PCM data is input from the buffer 23 into the coefficient multiplier 31₁, and the output data of the coefficient multiplier 31₁ is supplied to one of the inputs of the adder 33₁. The addition result data produced by the adder 33₁ is supplied to the delay element 34₁, and the output of the delay element 34₁ serves as an output of the IIR filter 29₁. The output data of the delay element 34₁ is returned to the other input of the adder 33₁ via the coefficient multiplier 32₁. The other IIR filters 29₂ to 29ⱼ are constituted similarly to the IIR filter 29₁. The multiplication coefficients of the coefficient multipliers 31₁ to 31ⱼ in the respective IIR filters 29₁ to 29ⱼ are k1, k2, . . . , kj, respectively, and the multiplication coefficients of the coefficient multipliers 32₁ to 32ⱼ are g1, g2, . . . , gj, respectively. Delay parameters of the delay elements 34₁ to 34ⱼ are Z⁻ⁿ¹, Z⁻ⁿ², . . . Z^{-nj}, respectively. The adder 30 adds the output data of the IIR filters 29₁ to 29ⱼ, and outputs the addition result as interpolated PCM data.

It is assumed that the audio feature amount detecting unit 27 and interpolation parameter generating unit 28 are both operated by a single control operation performed by a CPU not shown in the drawing.

Next, the operations of the audio feature amount detecting unit 27 and interpolation parameter generating unit 28 will be explained in detail.

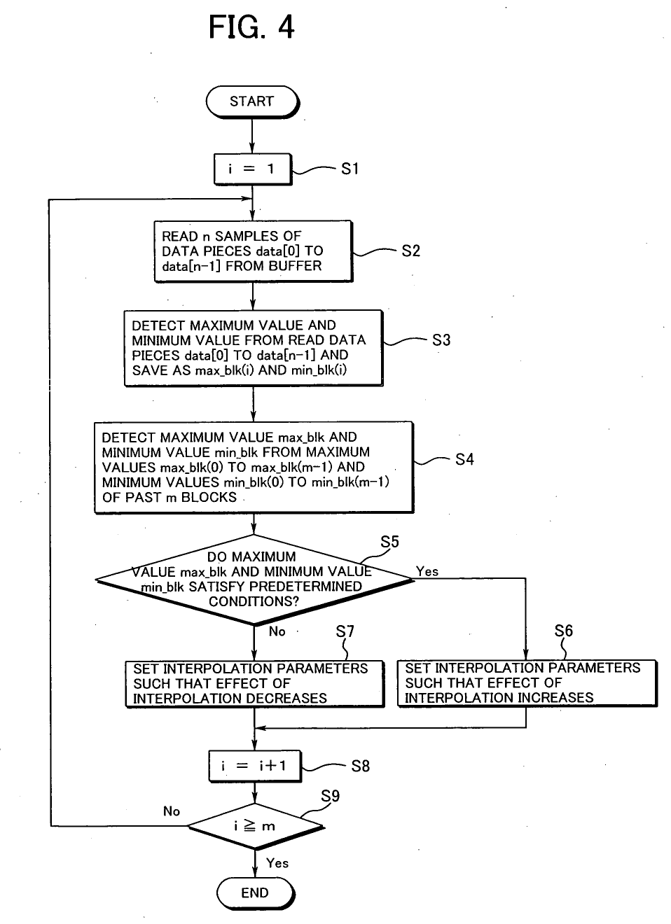

As shown in FIG. 4, first, the CPU sets a variable i to 0 (step S1). Then, n samples of data pieces data[0] to data[n−1] are read from the PCM data stored in the buffer 23 (step S2). The n samples equal one block, corresponding to one frame of input data, and are constituted by 1024 samples, for example. Each of the data pieces data[0] to data[n−1] has 16 bits.

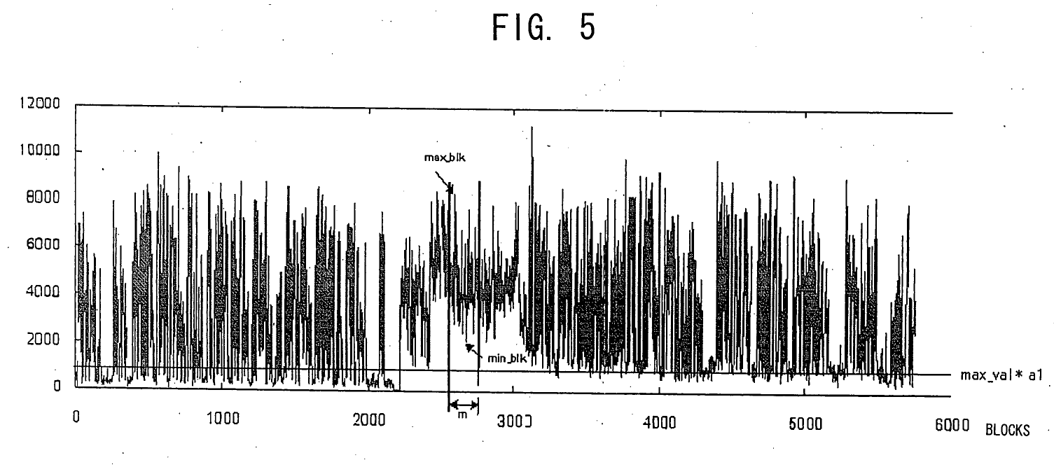

The maximum value and minimum value of the read data pieces data[0] to data[n−1] are detected and saved as a maximum value max_blk(i) and a minimum value min_blk(i) (step S3). A maximum value max_blk and a minimum value min_blk are then detected from maximum values max_blk(0) to max_blk(m−1) and minimum values min_blk(0) to min_blk(m−1) of the past m blocks, including the current maximum value max_blk(i) and minimum value min_blk(i) (step S4). For example, m equals 50. FIG. 5 shows an example of the maximum value max_blk and minimum value min_blk in the range of a specific set of m blocks when the audio signal level (absolute value) changes over time.

When the maximum value max_blk and minimum value min_blk are obtained, a determination is made as to whether or not they satisfy predetermined conditions (step S5). The predetermined conditions are min_blk>max_val*a1 and min_blk>max_blk*a2. max_val is the maximum value at which the data pieces data[0] to data[n−1] can be obtained. Hence, in the case of 16 bit data, max_val equals 32767, for example. a1 is a first coefficient which satisfies 0<a1<1, and equals approximately 0.1, for example. a2 is a second coefficient which satisfies 0<a2<1, and equals approximately 0.3, for example. max_val*a1 is the level shown in FIG. 5, for example.

When the predetermined conditions are satisfied, the interpolation parameters k1, k2, . . . , kj, g1, g2, . . . , gj are set such that the effect of the interpolation increases (step S6). If, on the other hand, the predetermined conditions are not satisfied, the interpolation parameters k1, k2, . . . , kj, g1, g2, . . . , gj are set such that the effect of the interpolation decreases (step S7). The steps S6 and S7 serve as filter characteristic setting means. More specifically, if the predetermined conditions are satisfied, this indicates continuous sound such as music in which sound continues at a level that is detectable by the listener, and therefore the values of k1, k2, . . . , kj, g1, g2, . . . , gj are set high in the step S6 such that the interpolation processing unit 24 has a filter characteristic whereby the signal level indicated by the output data decreases gradually in each of the IIR filters 29₁ to 29ⱼ. On the other hand, if the predetermined conditions are not satisfied, this indicates intermittent sound such as the vocalized sound of an announcer on a news program, which includes low-level blocks that can be detected by the listener among the m block sets, and therefore the values of the interpolation parameters are set low in the step S7 such that the interpolation processing unit 24 has a filter characteristic whereby the signal level indicated by the output data decreases rapidly in each of the IIR filters 29₁ to 29ⱼ. Only a part of the interpolation parameters k1, k2, . . . , kj, g1, g2, . . . , gj may be altered, rather than changing all of the values of the interpolation parameters.

After executing the step S6 or S7, 1 is added to the variable i (step S8), and a determination is made as to whether or not i is equal to or greater than m (step S9). If i<m, the process returns to the step S2 and the operation described above from the step S2 to the step S9 is repeated. On the other hand, if i≧m, the process ends.

The steps S2 to S4 correspond to an operation of the audio feature amount detecting unit 27, and the steps S5 to S7 correspond to an operation of the interpolation parameter generating unit 28.

As a result of these operations of the audio feature amount detecting unit 27 and interpolation parameter generating unit 28, the filter characteristics of the IIR filters 29₁ to 29ⱼ in the interpolation processing unit 24 are set, and in the frame (block) indicated by the switching signal, the interpolated PCM data obtained by these filter characteristics are output by the output switching unit 26 in place of the PCM data supplied by the delay unit 25. The PCM data output by the output switching unit 26 are reproduced by a reproduction apparatus not shown in the drawing, and then output as reproduced sound by electro-acoustic transducing means such as speakers.

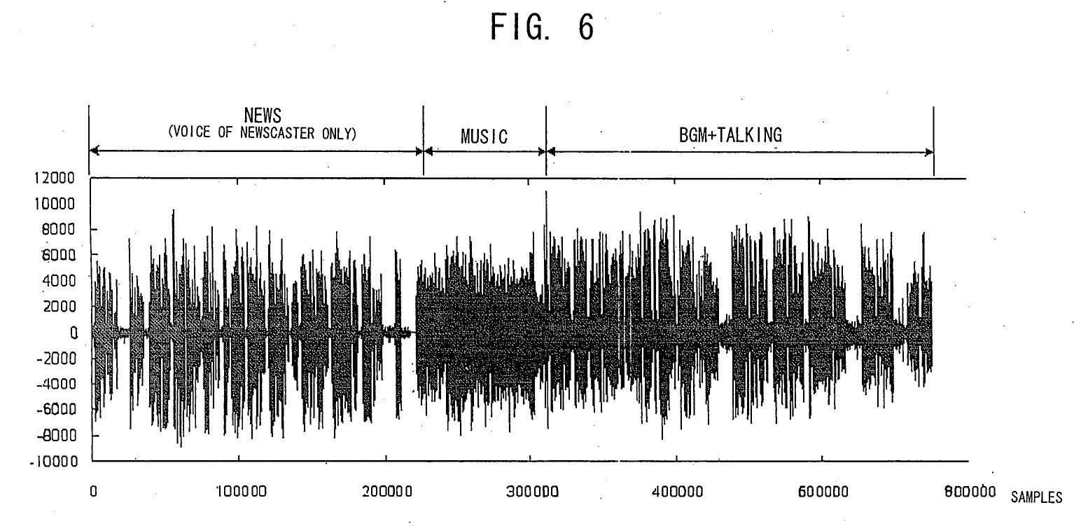

As shown in FIG. 6, in the case of a music audio signal, low-level areas almost never occur in the signal level, and therefore the minimum value min_blk is high. However, in the case of an audio signal constituted by the voice of a newscaster, low-level areas occur frequently, and therefore the minimum value min_blk is lower. In the embodiment described above, an audio signal constituted by music and an audio signal constituted by the voice of a newscaster are detected, and the interpolation parameters k1, k2, . . . , kj, g1, g2, . . . , gj are set appropriately in accordance with the detection result. Hence, when the audio signal indicates music, reproduced sound which varies continuously is obtained even in the portions where errors exist, and when the audio signal indicates the voice of a newscaster, reproduced sound generated by the repeated components of the IIR filters 29₁ to 29ⱼ in the interpolation processing unit 24 are eliminated from the portions where errors exist. As a result, unnatural feeling by the listener in relation to the reproduced sound of the interpolated portion can be reduced.

When the audio signal indicates the voice of a newscaster, it is desirable to make the reproduced sound generated by the interpolated PCM data less noticeable by applying comparatively fast fade-out from the level of the PCM data before the error position.

Further, as shown in FIG. 6, when the audio signal indicates BGM (background music) and a talking voice, low level areas occur, but the minimum value min_blk is higher than the minimum value min_blk when the audio signal indicates the voice of a newscaster. The interpolation parameters k1, k2, . . . , kj, g1, g2, . . . , gj may be also set appropriately in the case of an audio signal indicating BGM and a talking voice, independently of cases in which the audio signal indicates music or the voice of a newscaster.

The operations of the audio feature amount detecting unit 27 and interpolation parameter generating unit 28 described above may be executed only when an error is detected by the error position detecting unit 21, or may be repeated every m blocks regardless of error detection.

Furthermore, in the embodiment described above the audio feature amount is detected by the audio feature amount detecting unit 27 from the PCM data, but in the case of the audio signal data of a broadcast program, when PCM data is not used, the audio feature amount may be detected from program information such as an EPG (electronic program guide). Further, instead of detecting the maximum value and minimum value of the audio signal level from the PCM data, the frequency components of the audio signal may be detected as the audio feature amount. For example, an audio signal having a large amount of high frequency components is determined to be music, and an audio signal constituted by the human voice band alone is determined to be narration.

Furthermore, in the embodiment described above only the data pieces before the error position is used by the interpolation processing unit 24 to create the interpolated PCM data, but the interpolated PCM data may be created using the data after the error position as well as the data before the error position. Also in the embodiment described above, the interpolation parameters k1, k2, . . . , kj, g1, g2, . . . , gj are varied, but the delay parameters Z⁻ⁿ¹, Z⁻ⁿ², . . . , Z^{-nj} may also be varied. Also, the recursive filter is not limited to the IIR filter having the constitution described in the above embodiment.

In the present invention, the filter is not limited to a recursive filter, and a non-recursive filter such as an FIR (finite impulse response) filter may be used.

The error position detecting unit 21 detects a frame which includes an error in the input data, but the method thereof is not limited to a method using the CRC of the error position detecting unit 11. Further, the input data are not limited to compressed data, and may be PCM data. If the input data are PCM data, the PCM generating unit 22 is not required.

The present invention may be applied widely in the field of audio signal reproducing and recording apparatuses, to apparatuses having a function for detecting audio errors. In particular, the present invention may be applied to fields of use such as mobile broadcast reception and network music delivery, in which a high error frequency can be expected.

The present invention described above comprises error position detecting means for detecting an error position in audio data, audio feature amount detecting means for detecting the feature amount of the audio data, interpolated data creating means for creating interpolated data corresponding to the error position in the audio data using a filter having a filter characteristic that corresponds to the feature amount of the audio data, in accordance with at least data pieces before the error position of the audio data, and means for replacing the data portion in the error position of the audio data with the interpolated data, and therefore unnatural feeling by a listener in relation to the reproduced sound of the interpolated portion can be reduced.

This application is based on Japanese Patent Application No. 2004-333948 which is hereby incorporated by reference.

What is claimed is:

1. An audio data interpolation apparatus for interpolating an error portion of audio data, comprising:
an error position detecting unit which detects an error position in said audio data;
an audio feature amount detecting unit which detects a feature amount of said audio data;
an interpolated data creating unit which creates interpolated data corresponding to said error position of said audio data using a filter having a filter characteristic that corresponds to said feature amount of said audio data, in accordance with at least data pieces before said error position of said audio data; and
a switching unit which replaces the data portion at said error position of said audio data with said interpolated data.

2. The audio data interpolation apparatus according to claim 1, wherein said error position detecting unit detects said error position of said audio data in block units.

3. The audio data interpolation apparatus according to claim 1, wherein said audio feature amount detecting unit detects as said feature amount a maximum value and a minimum value of the amplitude of said audio data for each predetermined sample number range, and
said interpolated data creating unit includes:
a determining portion which determines whether or not said maximum value and said minimum value satisfy predetermined conditions; and
a filter characteristic setting portion which sets said filter to have a filter characteristic whereby a signal level indicated by output data decreases gradually when said maximum value and said minimum value satisfy said predetermined conditions, and sets said filter to have a filter characteristic whereby a signal level indicated by output data decreases rapidly when said maximum value and said minimum value do not satisfy said predetermined conditions.

4. The audio data interpolating apparatus according to claim 3, wherein said predetermined conditions are min_blk>max_val*a1 and min_blk>max_blk*a2, where min_blk is said minimum value, max_blk is said maximum value, max_val is a maximum value that can be taken by said audio data, a1 is a first coefficient, and a2 is a second coefficient that is greater than said first coefficient.

5. The audio data interpolation apparatus according to claim 3, wherein said filter characteristic setting portion sets a multiplication coefficient of a multiplier of said filter.

6. The audio data interpolation apparatus according to claim 1, wherein said filter is a recursive filter.

7. An audio data interpolation method for interpolating an error part of audio data, comprising the steps of:
detecting an error position in said audio data;
detecting a feature amount of said audio data;
creating interpolated data corresponding to said error position of said audio data using a filter having a filter characteristic that corresponds to said feature amount of said audio data, in accordance with at least data pieces before said error position of said audio data; and
replacing the data portion at said error position of said audio data with said interpolated data.
